(19) United States
(12) Patent Application Publication
(10) Pub. No.: US 2022/0173265 A1
(43) Pub. Date: Jun. 2, 2022

(54) DEVICE AND METHOD FOR TREATING WAFERS

(71) Applicant: FRAUNHOFER-GESELLSCHAFT ZUR FÖRDERUNG DER ANGEWANDTEN FORSCHUNG E.V., München (DE)

(72) Inventor: Martin ZIMMER, Friesenheim (DE)

(21) Appl. No.: 17/425,802

(22) PCT Filed: Jan. 30, 2020
(86) PCT No.: PCT/EP2020/052344

§ 371 Date: Jul. 26, 2021

(30) Foreign Application Priority Data
Jan. 31, 2019 (DE) 10 2019 102 492.7

(51) Int. Cl. H01L 31/18; H01L 21/67; H01L 21/677; H01L 21/48

(52) U.S. Cl. CPC H01L 31/1876; H01L 21/67086; H01L 21/4846; H01L 21/6776; H01L 21/67754

(57) ABSTRACT

The present invention relates to a device and a method for the treatment of wafers. Proposed is a transport of the wafers in vertical alignment through the process solution which is used for the treatment of the wafers, whereby an increase of the throughput, a simplified aftertreatment of the exhaust air as well as a reduction of the consumption of components of the process solution are made possible. The invention can, inter alia, be used in the production of solar cells or also of printed boards, for example printed boards for the electrical industry.

### FIELD OF INVENTION

The present invention relates to a device and a method for the treatment of wafers. Proposed is a transport of the wafers in vertical alignment through the process solution which is used for the treatment of the wafers, whereby an increase of the throughput, a simplified aftertreatment of the exhaust air as well as a reduction of the consumption of components of the process solution are made possible. The invention can, inter alia, be used in the production of solar cells or also of printed boards, for example printed boards for the electrical industry.

### BACKGROUND OF THE INVENTION

The production of solar cells from multicrystalline silicon solar cells is known and comprises a wet-chemical texturing process. This process is normally conducted in continuous passing-through plants (inline etching plants) such as shown in FIG. 1. Here, the wafers (1) in horizontal alignment are transported through the plant on transport rolls (2). Holding-down rolls (3) make sure that the wafers do not lose the contact with the transport rolls. Within the plant, there are regions in which the wafers are subjected to a chemical process solution, either by spraying or by immersing. The process solution may be present in a process basin (4). Overflowing medium is returned into a tank (5) again through a pipe, and from there by means of a pump (6) it is again pumped into the process basin. In this method, the level of the process solution is impounded in the region of the transport rolls by the first and last pairs of transport and holding-down rolls so that the wafers completely are immersed into the process solution. The gap between transport and holding-down rolls corresponds to the thickness of the wafers (normally about 200 μm), and thus it can be neglected.

For the texturization a solution of hydrofluoric acid (HF) and nitric acid (HNO₃) is used. This solution reacts with silicon in a strongly exothermic reaction to hexafluoro-silicic acid (H₂SiF₆) and nitrogen monoxide (NO) which in contact with oxygen from air further reacts to nitrogen dioxide (NO₂).

Since in this method the wafers are guided through the plant in horizontal alignment, the wafers require the maximum area which limits the number of wafers being treated at the same time and thus the throughput of the plant. Thus, an increase of the throughput can only be achieved by a reduction of the process time or an enlargement of the plant in combination with an increase of the throughput speed. Since the process time with 60 to 90 seconds is already very low, a further reduction, while maintaining a robust process, is hardly possible anymore. The increase of the throughput speed together with an enlargement of the plant is not very profitable from an economic point of view, since the material required and thus the investment costs for the construction of a larger plant also increase.

In the treatment of wafers, basically, a distinction can be made between an inline method and a batch method. In an inline method the wafers are transported through the plant in rows one after the other. It is also possible to transport several rows of wafers at the same time side by side (multi-lane inline method). In contrast thereto, in the batch process the wafers are not transported individually lying on a conveyor belt or the like, but with the help of a carrier into which a plurality of wafers is stacked.

In DE 10 2006 054 846 A1 a device is proposed in which wafers within an inline plant are introduced into a transporting batch device for then being transported through the plant as batch. Subsequently, several such batches stacked on top of each other are guided through the plant, and at the end of the plant they are singularized again, wherein the transport in the batch mode can also be conducted such that the wafers during the transport are vertically aligned. But a mechanically and logistically sophisticated combination and singularization are necessary for combining inline method and batch method. The transport of vertically aligned wafers in an inline method is not envisaged.

### SUMMARY OF THE INVENTION

In the light of this, therefore, it is an object of the present invention to provide a device and a method for the treatment of wafers which overcome the disadvantages of prior art. In particularly, an increased throughput should be made possible. In addition, a simplified aftertreatment of the exhaust air as well as a reduction of the consumption of components of the process solution should be achieved.

The object is solved by the subject matter of the patent claims. The object is in particularly solved by a device for the treatment of wafers with a chemical process solution, wherein the device comprises means of transport (2) and holding-down means (3) as well as at least one process basin (4) for holding the chemical process solution, wherein the process basin (4) on at least one side is limited by an impounding device (21), characterized in that the impounding device (21) is designed such that between the means of transport (2) and the holding-down means (3) vertically aligned wafers in horizontal movement direction can be guided into the process basin (4) and out of the process basin (4). A device of the invention according to exemplary embodiments is shown in the FIGS. 2 and 5.

When in the present description the terms “vertical” and “horizontal” are used, then this means “substantially vertical” and “substantially horizontal”, respectively, unless otherwise stated. As reference point, preferably, the surface of the process solution being present in the process basin (4) can be used. In the absence of undulations or other movements of the process solution, this surface is horizontally aligned. Thus, a surface vector which is perpendicular with respect to the surface of the process solution is vertical. Therefore, the phrase “substantially horizontal” preferably describes an orientation or movement which is substantially parallel to the surface of the process solution which is present in the process basin (4), while the phrase “substantially vertical” describes an orientation or movement which is substantially orthogonal to the surface of the process solution which is present in the process basin (4).

Preferably, a surface vector which is perpendicular with respect to a substantially horizontally oriented surface forms with a surface vector which is perpendicular with respect to the surface of the process solution an angle of at most 20°, further preferably at most 10°, further preferably at most 5°, further preferably at most 1°, further preferably about 0°. Preferably, the vector of a substantially horizontal movement direction forms with a surface vector which is perpendicular with respect to the surface of the process solution an angle of at least 70° and at most 110°, further preferably of at least 80° and at most 100°, further preferably of at least 85° and at most 95°, further preferably of about 90°.

Preferably, a surface vector which is perpendicular with respect to a substantially vertically oriented surface forms with a surface vector which is perpendicular with respect to the surface of the process solution an angle of at least 70° and at most 110°, further preferably of at least 80° and at most 100°, further preferably of at least 85° and at most 95°, further preferably of about 90°. Preferably, the vector of a substantially vertical movement direction forms with a surface vector which is perpendicular with respect to the surface of the process solution an angle of at most 20°, further preferably at most 10°, further preferably at most 5°, further preferably at most 1°, further preferably about 0°.

The device of the present invention is a device for the treatment of wafers with a chemical process solution. Preferably, with the help of the device according to the present invention silicon wafers, in particularly multicrystalline or monocrystalline silicon wafers, should be subjected to a texturing process. Thus, preferably, the treatment of the wafers is a texturization. Such a texturization of wafers is known and is mainly used in the production of solar cells. Preferably, the process solution used for multicrystalline wafers contains hydrofluoric acid (HF) and nitric acid (HNO₃), and the one used for monocrystalline wafers contains a mixture of aqueous potassium hydroxide solution (KOH) and one or more organic additives.

The device of the present invention comprises a process basin (4) for holding the chemical process solution. The device may also comprise several process basins (4), for example for the parallel treatment of several wafers or for the sequential treatment of one wafer with different process solutions. It is also possible to treat several wafers at the same time and/or one after another in the same process basin (4).

According to preferred embodiments of the invention, process basins (4) with rectangular base area are used. The width of the process basin (4) mainly depends on the number of the wafers which have to be treated in parallel manner as well as their thickness and distance from each other. Preferably, the width of the process basin (4) is in a range of 100 mm to 1000 mm, further preferably of 200 mm to 800 mm, further preferably of 500 mm to 700 mm. The length of the process basin (4) mainly depends on the desired process time during which the wafers should be in the process basin (4), wherein the transport speed of the wafers through the process basin (4) has to be considered. Preferably, the length of the process basin (4) is in a range of 100 mm to 5000 mm, further preferably of 300 mm to 4000 mm, further preferably of 800 mm to 3000 mm. The height of the process basin (4) mainly depends on the dimensions of the wafers which have to be treated, thus due to the vertical alignment it depends on their length and width, respectively. Preferably, the process basin (4) has a height which allows an impounding of the process solution to a height which exceeds the height of the wafers so that the wafers in the process basin (4) are completely immersed in the process solution. Preferably, the height of the process basin (4) is in a range of 20 mm to 2000 mm, further preferably of 50 mm to 1000 mm, further preferably of 100 mm to 500 mm, further preferably of 150 mm to 300 mm, further preferably of 160 mm to 250 mm, further preferably of 180 mm to 220 mm.

The device of the present invention comprises means of transport (2) and holding-down means (3). The means of transport (2) are used for the transport of the wafers through the device. The holding-down means (3) make sure that the wafers do not lose the contact with the means of transport (2). Means of transport (2) and holding-down means (3) are arranged such that the wafers can vertically be aligned between the means of transport (2) and the holding-down means (3) and can be guided in horizontal movement direction through the device, in particularly into the process basin (4), through the process basin (4) and out of the process basin (4).

The distance between the means of transport (2) and the holding-down means (3) preferably corresponds substantially to the length or the width of the wafers and not to the thickness of the wafers like in prior art. The distance between the means of transport (2) and the holding-down means (3) is determined by the vertical alignment of the wafers between the means of transport (2) and the holding-down means (3). In certain embodiments, the means of transport (2) and/or the holding-down means (3) are arranged in a movable manner in vertical direction so that the distance between them can be adjusted to the length or width of the treated wafers in a flexible manner. Normally, the length of the wafers corresponds to the width of the wafers. Thus, normally, the wafers have a square base area.

Preferably, the clearance between the means of transport (2) and the holding-down means (3) is in a range of 10 mm to 1000 mm, further preferably of 20 mm to 500 mm, further preferably of 50 mm to 300 mm, further preferably of 100 mm to 200 mm, further preferably of 150 mm to 170 mm, further preferably about 156 mm.

Preferably, within the device the means of transport (2) and the holding-down means (3) are aligned substantially parallel to each other. This is also advantageous for the vertical alignment of the wafers between the means of transport (2) and the holding-down means (3).

The means of transport (2) and/or the holding-down means (3) may, for example, be designed in the form of conveyer belts. Such embodiments of the invention are possible, but, however, they are less advantageous, because such conveyer belts together with the wafers have to be guided through the device, in particularly also into the process basin (4), through the process basin (4) and out of the process basin (4). So, besides the guiding of the wafers into and out of the process basin (4), there is the problem of the guiding of the conveyer belts into the process basin (4) and the guiding of the conveyer belts out of the process basin (4), whereby the possibilities for the design of the impounding device (21) are restricted considerably.

Particularly preferably, therefore, the means of transport (2) are transport rolls (2) and the holding-down means (3) are holding-down rolls (3). The design in the form of rolls has the advantage that a transport of the wafers through the device, in particularly also into the process basin (4), through the process basin (4) and out of the process basin (4), is possible without the necessity that also the means of transport (2) and the holding-down means (3) themselves have to be guided into the process basin (4), through the process basin (4) and out of the process basin (4). In particularly, preferably, the transport rolls (2) and the holding-down rolls (3) are fixed in place. Thus, during the transport of the wafers, preferably, the rolls only execute a rotational movement, but not a translational movement. Thus, preferably, the rolls do not move together with the wafers through the device, but remain in place. This results in various degrees of freedom, when the impounding device (21) is designed, because they only have to make possible the transport of the wafers into the process basin (4), through the process basin (4) and out of the process basin (4), however not the transport of the means of transport (2) and the holding-down means (3), since it is not necessary that they are guided into the process basin (4), through the process basin (4) and out of the process basin (4). Instead of that, preferably, inside and outside the process basin transport rolls (2) and holdings-down rolls (3) are provided which remain in place each.

[symbol]

preferably at most 40% of the wafer length, further preferably at most 30% of the wafer length. Preferably, the thickness of the impounding device (21) is in a range of 15 mm to 80 mm, further preferably of 20 mm to 60 mm, further preferably of 30 mm to 50 mm.

The width of the slot (22) is preferably at most 5 times, further preferably at most 3 times the wafer thickness, however preferably at least 1.1 times, further preferably at least 1.5 times the wafer thickness. Preferably, the width of the slot (22) is in a range of 220 μm to 1000 μm, further preferably of 300 μm to 600 μm.

Preferably, the slots (22) are chamfered on the entry side, that is, the edge between the front section and the slot (22) is preferably provided with a chamfer. This allows that the wafers also in the case of tolerances in the transport system can still be inserted in a particularly reliable manner.

Preferably, the width of the slots (22) tapers in process flow direction. This makes a contribution to a still better guidance of the wafers through the slots (22). In such embodiments, the above-mentioned width of the slots (22) means the width of the slots (22) at the narrowest point. In the case of a tapering slot width the ratio of the slot width at the broadest point to the slot width at the narrowest point is preferably in a range of 1.1:1 to 2:1, further preferably of 1.2:1 to 1.5:1.

In certain preferred embodiments, the holding-down means (3) before the impounding device (21) have a design with an additional weight for guaranteeing a particularly good guidance against the outflowing liquid.

The device of the present invention is suitable for conducting inline methods, as already follows from the alignment of the wafers between means of transport (2) and holding-down means (3) as well as from the transport of the wafers through the device thus guaranteed. In an inline method the wafers are transported individually through the plant in rows one after the other. It is also possible to transport several rows of wafers at the same time side by side (multi-lane inline method).

In prior art without problems the process basin (4) can be limited by the transport rolls (2) and the holding-down rolls (3), because there the wafers are transported in horizonal alignment so that the distance between the transport rolls (2) and the holding-down rolls (3) substantially corresponds to the thickness of the wafers. Since the thickness of the wafers is very low (normally about 200 μm), the gap between the transport rolls (2) and the holding-down rolls (3) does not result in a considerable leakage of the process liquid from the process basin (4).

In contrast thereto, the present device involves the inline transport of vertically aligned wafers into the process basin (4), through the process basin (4) and out of the process basin (4). Due to the vertical alignment of the wafers, the distance of the means of transport (2) and the holding-down means (3) does not correspond to the thickness of the wafers such as in prior art, but to the length or the width of the wafers, wherein length and width of the wafers due to the normally square base area of the wafers are normally identical. Length and width of the wafers exceed their thickness many times, normally at least 100 times. Therefore, the distance between the means of transport (2) and the holding-down means (3) is so high that the process basin (4) cannot be limited by the means of transport (2) and the holding-down means (3), because the process solution would leak through the space between means of transport (2) and holding-down means (3) so that the process solution would not remain in the process basin (4) in an amount which is sufficient for the treatment of the wafers.

To limit the process basin (4) on all sides by common boundary walls is not a satisfying solution for a device which should be suitable for carrying out an inline method. Because so it would be prevented that the vertically aligned wafers can be guided in horizontal movement direction into the process basin (4) and out of the process basin (4). Rather, it would be necessary to vertically lift the wafers, guide them over the boundary wall and subsequently vertically lower them into the process basin (4) which would not be consistent with an inline method.

Therefore, the process basin (4) of the device of the present invention is limited on at least one side by an impounding device (21) which is designed such that it is possible to guide between the means of transport (2) and the holding-down means (3) vertically aligned wafers in horizontal movement direction into the process basin (4) and out of the process basin (4). One or more of the other sides of the process basin (4) also can be limited by such an impounding device (21). But, however, this is not necessary for conducting an inline method with the device. It is sufficient, when the process basin (4) is limited on at least one side by such an impounding device (21). In such an embodiment, the wafers are guided out of the process basin (4) on the same side on which they have also been guided into the process basin (4). The residual sides of the process basin (4) may, for example, be designed in the form of normal boundary walls for avoiding leakage of the process solution from the process basin (4).

However, embodiments with the described impounding device (21) on only one side of the process basin require a more complex transport guidance of the wafers within the process basin (4), because the wafers leave the process basin (4) on the same side on which they have entered the process basin (4). Therefore, preferably, the device of the invention comprises two impounding devices (21a, 21b) which are present on opposite sides of the process basin (4). This allows a linear transport of the wafers into the process basin (4), through the process basin (4) and out of the process basin (4), because the wafers can enter the process basin (4) on one side and can leave the process basin (4) on the opposite side of the process basin (4). In such embodiments a change of the movement direction of the wafers is not necessary.

The material of the impounding device (21) depends on the respective use, in particularly the process temperature and/or the constituents of the chemical etching solution.

The impounding device (21) of the present invention is designed such that between the means of transport (2) and the holding-down means (3) vertically aligned wafers in horizontal movement direction can be guided into the process basin (4) and out of the process basin (4).

In certain embodiments, the impounding device (21) is arranged in a movable manner such that the impounding device (21) can assume an open position and a closed position, wherein the open position allows the guidance of the vertically aligned wafers into the process basin (4) and/or the guidance of the vertically aligned wafers out of the process basin (4). For example, the impounding device (21) can be designed such that it can be lowered downwards into the open position or lifted or pulled upwards into the open position for allowing a guidance of the vertically aligned wafers into the process basin (4) and/or a guidance of the vertically aligned wafers out of the process basin (4).

Such a design of the invention is possible, but, however, it involves certain disadvantages. Because the chemical process solution will in such cases leak from the process basin (4) in a considerable extent, when the impounding device (21) is in the open and not in the closed position. Therefore, the device of the present invention with a such designed impounding device (21) cannot be used for continuous operation. Rather, the impounding device (21) after the loading of the wafers into the process basin (4) has to be caused to change from the open position into the closed position, so that process liquid fed into the process basin (4) again leaks from the process basin (4) through the opening of the process basin (4) which results from the fact that the impounding device (21) is in the open position. This requires a stop of the transport of the wafers through the plant. Only when the impounding device (21) is again in the closed position, then the process solution is given into the now closed process basin (4). For allowing the guidance of the wafers out of the process basin (4), then the impounding device (21) has again to be brought into the open position. Before, preferably, the process liquid or at least a majority thereof is again removed from the process basin (4) for avoiding an uncontrolled leakage of the process liquid from the process basin (4), when the impounding device (21) is in the open position.

For avoiding an excessive leakage of process liquid from the process basin (4), the impounding device (21) can also be designed such that via two weirs 21a and 21b a loading region and via two weirs 21c and 21d an unloading region are formed. A possible design is, for example, shown in FIG. 6. Here, the weirs 21a, 21b, 21c and 21d each are shown as retractable weirs. In an alternative, it is also possible to lift or pull the weirs upwards into the open position. Due to the fact that two weirs each form a loading region and an unloading region, respectively, an excessive leakage of process liquid from the process basin (4) can be avoided. A similar principle, for example, is known from locks in inland waterway transport.

In this mode of operation, it is necessary to divide the wafers into groups of wafers, because the wafers are guided into and out of the process basin (4) in groups each. Normally, the distance between two consecutive wafer groups will be at least one wafer length so that this results in increased space requirements. In multi-lane inline methods in which several wafer groups in a parallel manner are guided into the process basin (4) and out of the process basin (4), in addition, it has to be guaranteed that the single wafers in fact are parallel to each other, because otherwise it may be possible that undesired interactions of wafers which are out of line with the impounding device (21) occur, when the impounding device (21) is changed from the open into the closed position, wherein this may result in damage of the respective wafers and/or the impounding device (21).

Therefore, preferable is a design of the impounding device (21) which allows a continuous operation of the device. Preferably, the impounding device (21) is provided with at least one vertically running slot (22) for guiding through the vertically aligned wafers. For single-lane inline methods it is sufficient, when the impounding device (21) is provided with exactly one vertically running slot (22) for guiding through the vertically aligned wafers. In multi-lane inline methods several rows of wafers are transported at the same time side by side. For such cases, the impounding device (21) can be provided with more than one vertically running slot (22) for guiding through the vertically aligned wafers. In particularly, the number of the slots (22) should correspond to the number of the rows of wafers which are processed in a parallel manner. In preferable embodiments, the impounding device (21) is provided with 2 to 1000, further preferably 5 to 500, further preferably 10 to 200, further preferably 20 to 100, further preferably 30 to 50 vertically running slots (22) for guiding through the vertically aligned wafers. An exemplary embodiment of an impounding device (21) with slots (22) is shown in FIG. 3.

The distance of the slots (22) from each other depends on the distance of the rows of wafers which are processed in parallel manner. Preferably, the distance of the slots (22) from each other is 2 times to 100 times, further preferably 5 times to 50 times, further preferably 10 times to 30 times, further preferably 20 times to 25 times the width of the slots (22). Preferably, the distance of the slots (22) from each other is 0.4 mm to 40 mm, further preferably 1 mm to 10 mm, further preferably 2 mm to 6 mm, further preferably 4 mm to 5 mm, further preferably 4.5 mm to 4.9 mm, further preferably 4.7 mm to 4.8 mm.

The slots (22) can be introduced into the impounding device (21) in different ways. Preferably, the slots (22) are milled into the impounding device (21). In other preferred embodiments, the impounding device (21) is already prepared with slots (22), in particularly by means of additive manufacturing, for example 3D printing.

Preferably, the dimensions of the slots (22) correspond substantially to the dimensions of the wafers in the front view of the vertical alignment. This allows a guiding of the vertically aligned wafers in horizontal movement direction through the slots (22), without the need for unnecessarily large dimensions of the slots (22) which might involve an increased and undesired leakage of process solution from the process basin (4).

Preferably, the slots (22) have a height in a range of 10 mm to 1000 mm, further preferably of 20 mm to 500 mm, further preferably of 50 mm to 300 mm, further preferably of 100 mm to 200 mm, further preferably of 150 mm to 170 mm, further preferably of 156 mm to 168 mm, further preferably of 160 mm to 165 mm. Preferably, the height of the slots (22) substantially corresponds to the distance between the means of transport (2) and the holding-down means (3).

The width of the slot (22) is preferably at most 5 times, further preferably at most 3 times the wafer thickness, however preferably at least 1.1 times, further preferably at least 1.5 times the wafer thickness. The width of the slot (22) is preferably in a range of 220 μm to 1000 μm, further preferably of 300 μm to 600 μm.

The depth of the slots (22) depends on the depth of the impounding device (21). Preferably, the depth of the slots (22) is at least 10% of the wafer length, further preferably at least 15% of the wafer length, further preferably at least 20% of the wafer length, however preferably at most 50% of the wafer length, further preferably at most 40% of the wafer length, further preferably at most 30% of the wafer length. Preferably, the depth of the slots (22) is in a range of 15 mm to 80 mm, further preferably of 20 mm to 60 mm, further preferably of 30 mm to 50 mm.

So, with the device according to the present invention, it is possible to transport several rows of wafers (1), in particularly 2 to 1000 rows of wafers (1), for example 5 to 500 rows of wafers (1), 10 to 200 rows of wafers (1), 20 to 100 rows of wafers (1) or 30 to 50 rows of wafers (1) at the same time side by side through the same process basin (4). Preferably, the distance of two rows of wafers (1) from each other which are transported at the same time side by side through the process basin (4) is 0.4 mm to 40 mm, further preferably 1 mm to 10 mm, further preferably 2 mm to 6 mm, further preferably 4 mm to 5 mm, further preferably 4.5 mm to 4.9 mm, further preferably 4.7 mm to 4.8 mm.

Preferably, the device comprises a tank (5) which is connected with the process basin (4) in such a way that chemical process solution can be transferred from the tank (5) into the process basin (4). Preferably, the device comprises a pump (6) for transferring the chemical process solution from the tank (5) into the process basin (4).

Preferably, the device comprises at least one collecting basin for receiving process solution leaking from the process basin (4). Preferably, the collecting basin is connected with the tank (5) such that process solution received in the collecting basin can be returned into the tank (5). So, it is achieved that process solution leaking from the process basin (4) is not lost, but can again be used for the treatment of the wafers.

The present invention also relates to an inline method for the treatment of wafers with a chemical process solution comprising the following steps:
a) providing of vertically aligned wafers,
b) providing of a process basin (4) with process solution being present therein,
c) guiding of the vertically aligned wafers into the process basin (4),
d) guiding of the vertically aligned wafers through the process basin (4) and the process solution being present therein so that the wafers are contacted with the process solution,
e) guiding of the vertically aligned wafers out of the process basin (4),
   wherein the guiding into, guiding through and guiding out of steps according to the steps c) to e) are conducted in substantially horizontal movement direction. Preferably, the method is conducted with a device of the present invention.

The method of the present invention is an inline method. In an inline method the wafers are transported through the plant in a row one after the other. It is also possible to transport several rows of wafers at the same time side by side (multi-lane inline method).

Preferably, several rows of wafers (1), in particularly 2 to 1000 rows of wafers (1), for example 5 to 500 rows of wafers (1), 10 to 200 rows of waters (1), 20 to 100 rows of wafers (1) or 30 to 50 rows of wafers (1) are transported through the same process basin (4) at the same time side by side. Preferably, the distance of two rows of wafers (1) from each other which are transported at the same time side by side through the process basin (4) is 0.4 mm to 40 mm, further preferably 1 mm to 10 mm, further preferably 2 mm to 6 mm, further preferably 4 mm to 5 mm, further preferably 4.5 mm to 4.9 mm, further preferably 4.7 mm to 4.8 mm.

The method of the invention is a method for the treatment of wafers with a chemical process solution. Preferred wafers are silicon wafers, in particularly multicrystalline silicon wafers. The treatment of the wafers is preferably a texturization. Such a texturization of wafers is known and is mainly used in the production of solar cells. Preferably, the process solution used contains hydrofluoric acid (HF) and nitric acid (HNO₃).

According to step a) of the method according to the present invention, vertically aligned wafers are provided. Length and width of the wafers exceed their thickness many times, normally 100 times to 1000 times. From this follows, that wafers have two main surfaces which are each defined by length and width of the wafers. Also wafers with round main surfaces are conceivable, wherein here the main surfaces are limited by their circumference. A substantially vertical alignment of the wafers means an orientation in which both main surfaces of a wafer are arranged such that surface vectors which are perpendicular with respect to the main surfaces are substantially horizontally oriented. Preferably, the surface vectors of both main surfaces form with the vector of the horizontal movement direction of the wafers according to the movement of the steps c) to e) of the method an angle of at least 70° and at most 110°, further preferably of at least 80° and at most 100°, further preferably of at least 85° and at most 95°, further preferably of about 90°.

According to step b) of the method according to the present invention, a process basin (4) with process solution being present therein is provided. Preferably, the process solution contains hydrofluoric acid (HF) and nitric acid (HNO₃) in the case of texturization of multicrystalline wafers or a mixture of potassium hydroxide solution (KOH) and one or more organic additives in the case of texturization of monocrystalline wafers.

The treatment of the wafers with the chemical process solution is conducted by guiding the wafers through the process basin (4) so that the wafers are contacted with the process solution being present in the process basin (4). The period of time between the guiding of the wafers into the process basin (4) and the guiding of the wafers out of the process basin (4) is for multicrystalline wafers preferably 15 to 180 seconds, further preferably 30 to 120 seconds, further preferably 60 to 90 seconds, for monocrystalline wafers preferably 0.5 to 15 minutes, further preferably 1 to 10 minutes, further preferably 2 to 6 minutes.

The guiding into, guiding through and guiding out of steps (of the vertically aligned wafers) according to the steps c) to e) of the method according to the present invention are conducted in substantially horizontal movement direction. This means that the wafers are guided such that the distance of the gravity center of the single wafers from the surface of the process solution during the steps c) to e) substantially remains unchanged. Preferably, the difference between the largest distance and the smallest distance of the gravity center of the single wafers from the surface of the process solution during the steps c) to e) is at most 20%, further preferably at most 10%, further preferably at most 5%, further preferably at most 2%, further preferably at most 1% of the length of the respective wafer.

The speed of movement of the wafers during the steps c) to e) of the method is preferably in a range of 0.5 m/min to 10 m/min, further preferably of 1 m/min to 6 m/min.

The present invention also relates to the use of the device and/or the method of the invention for the production of solar cells and/or printed boards.

### DESCRIPTION OF THE FIGURES

FIG. 1 shows a cross-section through a device of prior art. The wafers (1) are transported in horizontal alignment through the device. The process basin (4) is limited by the transport rolls (2) and the holding-down rolls (3). Overflowing medium is returned into a tank (5) through a pipe, and from there by means of a pump (6) it is again pumped into the process basin (4). The arrows show the flow direction of the medium.

FIG. 2 shows a cross-section through a device of the present invention. The wafers (1) are transported in vertical alignment through the device. The device comprises a process basin (4) for holding the chemical process solution. The process basin (4) is limited on two sides by an impounding device (21). Overflowing medium is returned into a tank (5) through a pipe, and from there by means of a pump (6) it is again pumped into the process basin (4). The arrows show the flow direction of the medium. The treatment of the wafers (1) with the chemical process solution is achieved by guiding the wafers (1) through the process basin (4) with the process solution being present therein. The impounding device (21) is designed such that between the means of transport (2) and the holding-down means (3) vertically aligned wafers (1) in horizontal movement direction can be guided into the process basin (4) and out of the process basin (4).

FIG. 3 shows a front view of an impounding device (21) with slots (22) as passage for the wafers which are transported in vertical alignment.

FIG. 4 shows a front view of the transport rolls (2) and the holding-down rolls (3) with wafers (1) being vertically aligned between them.

FIG. 5 shows a perspective view of a device of the present invention. The impounding device (21) is designed such that between the means of transport (2) and the holding-down means vertically aligned wafers (1) in horizontal movement direction can be guided into the process basin (4) and out of the process basin (4). For reasons of clarity, the holding-down means are not shown.

FIG. 6 shows a cross-section through a device of the present invention with wafers (1) which are transported through the device in vertical alignment. The impounding device (21) is designed such that between the means of transport (2) and the holding-down means (3) vertically aligned wafers (1) in horizontal movement direction can be guided into the process basin (4) and out of the process basin (4), Shown is an embodiment in which the impounding device (21) is designed such that via two weirs 21a and 21b a loading region and via two weirs 21c and 21d an unloading region are formed. The weirs 21a, 21b, 21c and 21d each are retractable weirs. For loading and unloading, at first, the weirs 21a and 21c are lowered so that wafers can be moved into the loading and unloading region (FIG. 6A). Subsequently, the weirs 21a and 21c are transferred into the closed position so that the arrangement shown in FIG. 6B results. After transferring the weirs 21b and 21d into the opened position the wafer to be loaded (1) is transported into the process region, while the wafer to be unloaded ( ) leaves the unloading region (FIGS. 6C and 6D). When the loading and unloading regions are unoccupied again, then the weirs 21b and 21d are transferred into the closed position and the weirs 21a and 21b are transferred into the opened position so that the next wafers (1) each can be moved into the loading and unloading region, and again the arrangement shown in FIG. 6A results.

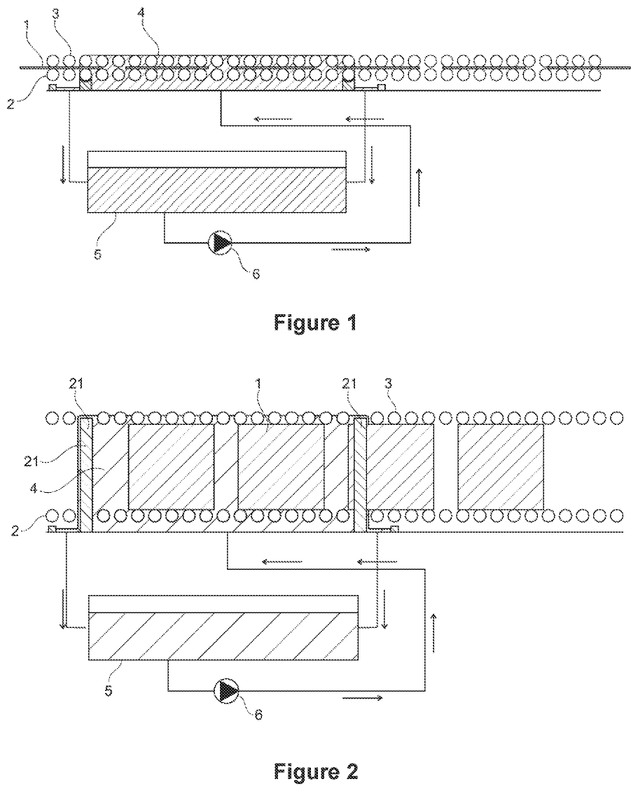

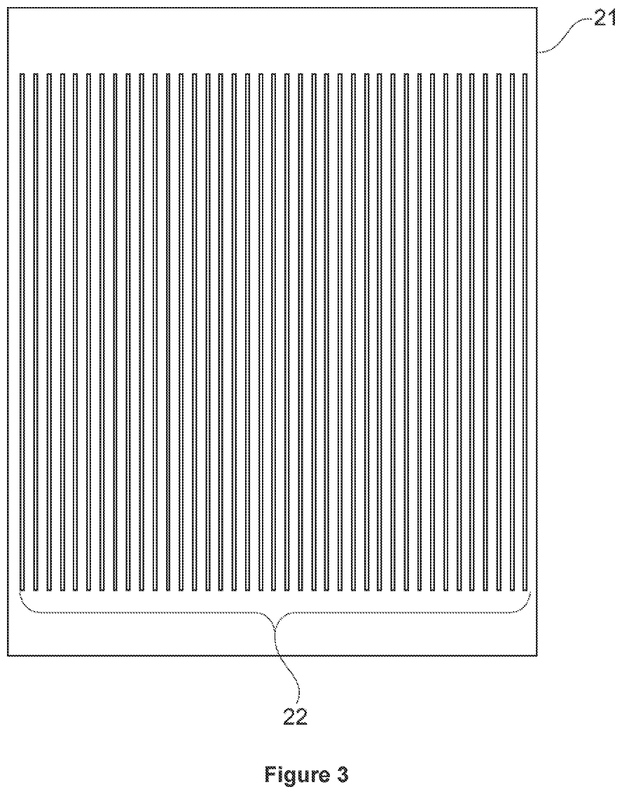

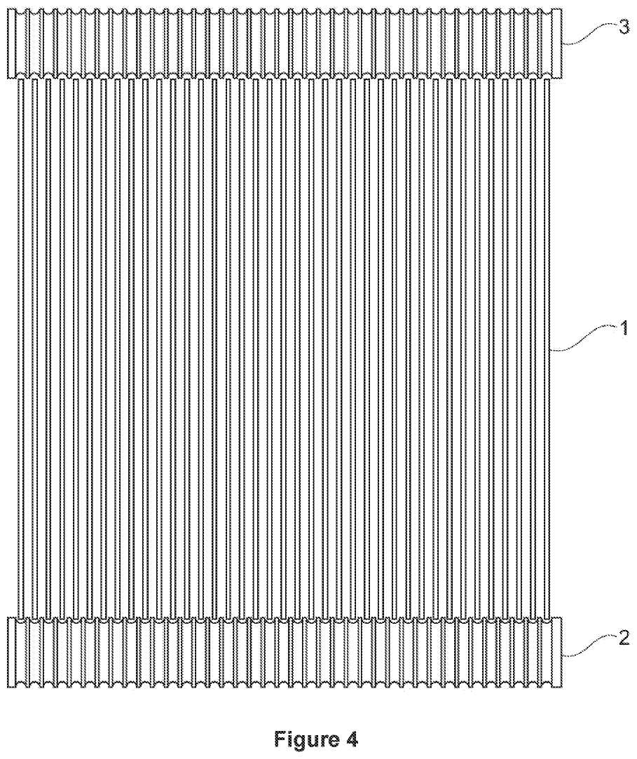

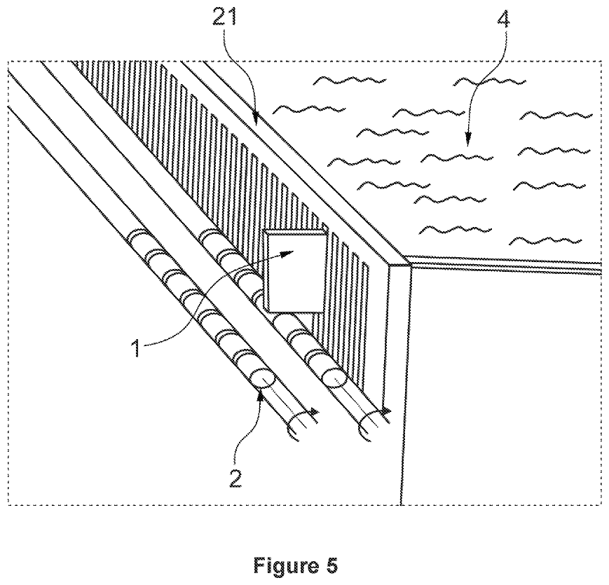

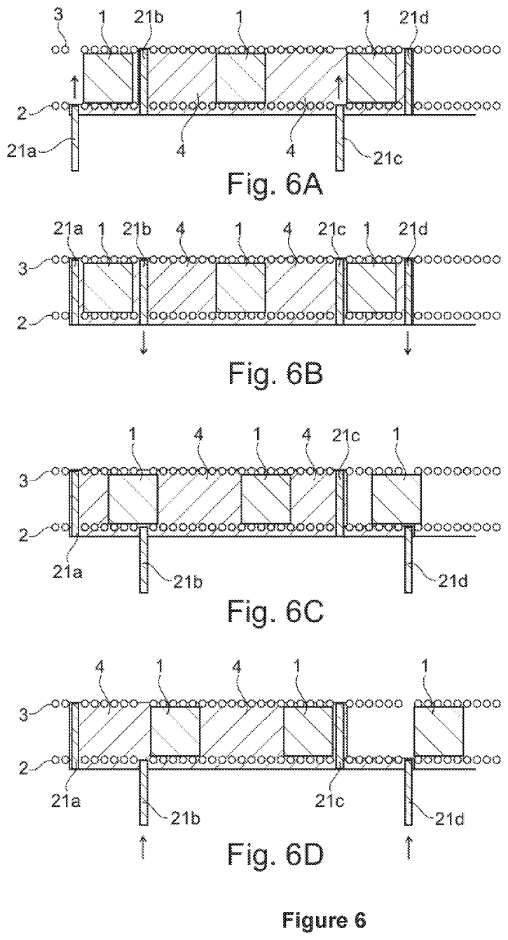

### DETAILED DESCRIPTION OF THE INVENTION

### EXAMPLES

Transport of vertically aligned wafers through a process plant

For the transport, in an edgewise and surface-parallel manner wafers are moved through a process plant. So, the space required per wafer is reduced from about 160×160 mm² to 160×5 mm² which results in a significant increase of the wafers being treated in parallel manner and thus in a significant increase of the throughput of the plant.

In contrast to prior art in which a horizontal alignment of the wafers during the transport is envisaged, in the present method an impounding of the process solution only by the transport and holding-down rolls is no longer possible, because now the distance between both rolls corresponds to the edge length of the wafers (156 mm). Therefore, the additional installation of an impounding device (21) is necessary. This impounding device (21) is provided with a number of slots (22) (which corresponds to the number of the wafers) through which the wafers can be moved into the impounded process solution. In the present case, 50 wafers are treated in parallel manner so that the impounding device (21) is provided with 50 slots (22).

For achieving a vertical alignment of the wafers which is as exact as possible, the transport rolls (2) and the holding-down rolls (3) are provided with a profile so that the wafers are guided in small recesses of the rolls and are protected against lateral tilting.

By the transport of the wafers in vertical alignment the throughput can significantly be increased.

Besides the higher throughput, the bath surface in relation to the number of the wafers which are treated at the same time is substantially smaller. So, oxides of nitrogen are released into the exhaust air in a more concentrated form which simplifies the aftertreatment thereof.

Furthermore, by the smaller bath surface the total load of oxides of nitrogen in the exhaust air is reduced. A part of the oxides of nitrogen remains in the process solution, and there it is reacted further. So, the consumption of nitric acid in the etching process is reduced.

What is claimed is:

1. A device for the treatment of wafers with a chemical process solution, wherein the device comprises means of transport and holding-down means as well as at least one process basin for holding the chemical process solution, wherein the process basin on at least one side is limited by an impounding device, wherein the impounding device is designed such that between the means of transport and the holding-down means vertically aligned wafers in horizontal movement direction can be guided into the process basin and out of the process basin.

2. The device according to claim 1, wherein the impounding device is provided with at least one vertically running slot for guiding through the vertically aligned wafers.

3. The device according to claim 2, wherein the slots have a height in a range of 10 mm to 1000 mm.

4. The device according to claim 3, wherein the slots have a width in a range of 220 μm to 1000 μm.

5. The device according to claim 1, wherein the impounding device is provided with 2 to 1000 vertically running slots for guiding through the vertically aligned wafers.

6. The device according to claim 5, wherein the distance of the slots from each other is 2 times to 100 times the width of the slots.

7. The device according to at least one of claim 5, wherein the distance of the slots from each other is 0.4 mm to 40 mm.

8. The device according to claim 1, wherein the impounding device is arranged in a movable manner such that the impounding device can assume an open position and a closed position, wherein the open position allows the guidance of the vertically aligned wafers into the process basin and/or the guidance of the vertically aligned wafers out of the process basin.

9. The device according to claim 1, wherein the distance between the means of transport and the holding-down means is in a range of 10 mm to 1000 mm.

10. The device according to claim 1, wherein the means of transport and/or the holding-down means comprise at least one recess for holding the wafers.

11. The device according to claim 1, wherein the impounding device is designed in the form of two impounding devices which are present on opposite sides of the process basin.

12. An inline method for the treatment of wafers with a chemical process solution comprising the following steps:
a) providing of vertically aligned wafers,
b) providing of a process basin with process solution being present therein,
c) guiding of the vertically aligned wafers into the process basin,
d) guiding of the vertically aligned wafers through the process basin and the process solution being present therein so that the wafers are contacted with the process solution,
e) guiding of the vertically aligned wafers out of the process basin,
wherein the guiding into, guiding through and guiding out of steps according to the steps c) to e) are conducted in substantially horizontal movement direction.

13. The method according to claim 12, wherein 2 to 1000 rows of wafers at the same time side by side are transported through the process basin.

14. The method according to claim 13, wherein the distance of two rows of wafers from each other which are transported at the same time side by side through the process basin is 0.4 mm to 40 mm.

15. The method according to claim 1 for the production of solar cells and/or printed boards using the device.

16. The device according to claim 3, wherein the slots have a width in a range of 220 μm to 1000 μm.

17. The device according to claim 6, wherein the distance of the slits from one another is from 0.4 mm to 40 mm.
